(19) United States
(12) Patent Application Publication
(10) Pub. No.: US 2011/0250414 A1
(43) Pub. Date: Oct. 13, 2011

(54) TCO COATING WITH A SURFACE PLASMA RESONANCE EFFECT AND MANUFACTURING METHOD THEREOF

(75) Inventors: Po-Kai Chiu, Hsinchu (TW); Shu-Te Ho, Taipei (TW); Bo-Heng Liou, Hsinchu (TW); Chien-Nan Hsiao, Hsinchu (TW); Wen-Hao Cho, Hsinchu (TW); Hung-Pin Chen, Hsinchu (TW); Din-Ping Tsai, Taipei (TW)

(73) Assignee: INSTRUMENT TECHNOLOGY RESEARCH CENTER, NATIONAL APPLIED RESEARCH LABORATORY, Hsinchu (TW)

(21) Appl. No.: 13/082,379

(22) Filed: Apr. 7, 2011

(30) Foreign Application Priority Data
Apr. 7, 2010 (TW) 099110677

(51) Int. Cl. B32B 7/02; C23C 14/46

(52) U.S. Cl. 428/212; 204/192.11

(57) ABSTRACT

A novel TCO coating and its manufacturing method are disclosed. The TCO coating of the present invention consists of titanium oxide, silicon oxide and metal. The TCO coating is manufactured according to electromagnetic field simulation software basing on the Maxwell Equations. Because the manufacturing method (including steam plating and sputter plating) of the present invention may be carried out under the room temperature, base boards that are made of polymer and that can not withstand high temperatures may be used and hence base boards may have wider applications. Also, less time is needed in the production, production cost is lowered and mass-production may be achieved.

### CROSS REFERENCE TO RELATED APPLICATIONS

This application claims priority of Taiwan Patent Application No. 099110677, filed on Apr. 7, 2010, the entirety of which is incorporated by reference herein.

### BACKGROUND OF THE INVENTION

1. Field of the Invention

The invention generally relates to a novel TCO (transparent conducting oxide) coating with a surface plasma resonance effect and its manufacturing method. More particularly, the invention relates to a TCO coating that is manufactured according to electromagnetic field simulation software basing on the Maxwell Equations and that is manufactured by a steam plating system or a sputter plating system under the room temperature or lower temperatures to enable the TCO coating to have wider applications.

2. Description of the Prior Art

TCO (transparent conducting oxide) has been a material that has wide applications and TCO has been widely used as the semiconductor technology advances. According to the literature, TCO first appeared in 1907 and CdO coating was made by the sputter method. However, at that time, the making of TCO was only for the purpose of research and the commercial applications of TCO emerged after 1940. The characteristics of TCO include the high penetration rate (higher than 80%) in the range of visible light and a high conductivity (with the resistivity lower than 0.001 ohm-cm). In addition, the smoothness of the surface of TCO and chemical stability are important factors in terms of application of TCO. Because TCO has a high conductivity, TCO has a high concentration of free electrons (about 1020 free electrons per cubic centimeter) and hence TCO has optical selectivity in the range of visible light. TCO reflects infrared radiation and absorbs ultraviolet radiation and allows the passage of visible light. Because TCO has these characteristics, TCO has been widely used in various types of photonic products, such as flat panel displays, solar cells, phototransistor, touch panel, light emitting elements, gas detector, PDP panels and heat insulation layer and heat reflective mirror used in buildings.

As of now, glass base board 1 with TCO coating has been widely used due to its high level of transparency and lower price. However, sodium ions in the glass board often enter the TCO coating and this would lower its conductivity. In addition, such glass board may be broken easily and larger glass boards are not easily manufactured.

From the above, we can see that the base board 1 of the prior art has many disadvantages and needs to be improved.

To eliminate the disadvantages in the prior art, the inventor has put a lot of effort into the subject and has successfully come up with the novel TCO coating and its manufacturing method of the present invention.

### SUMMARY OF THE INVENTION

An object of the present invention is to provide a TCO coating that can be manufactured at lower temperatures so that the TCO coating may have wider applications.

Another object of the present invention is to provide a manufacturing method by which less time is needed in the production and production cost is lowered.

To reach these objects, a novel TCO coating and its manufacturing method are disclosed. The TCO coating of the present invention consists of titanium oxide, silicon oxide and metal. The TCO coating is manufactured according to electromagnetic field simulation software basing on the Maxwell Equations. The manufacturing method includes steam plating (TCO coating is coated under the room temperature; ion generators are used to increase the denseness of the coating and to modify the thickness of the metallic membrane so that the manufacturing process may be carried out at lower temperatures) and sputter plating (the plating is carried out under the room temperature without the presence of oxygen; DC power is used to carry out the plating of the metallic target material and RF power is used to carry out the plating of the oxide target material). Therefore, the manufacturing method of the present invention may be carried out under the room temperature, base boards that are made of polymer and that can not withstand high temperatures may be used and hence base boards may have wider applications. Also, less time is needed in the production, production cost is lowered and mass production may be achieved.

### BRIEF DESCRIPTION OF THE DRAWINGS

FIG. 1 schematically illustrates the structure of the TCO coating of the present invention.

FIG. 2 illustrates the steam plating system with e-beam generators and ion generators in the present invention.

FIG. 3 illustrates the sputter plating system of the present invention.

FIG. 4 illustrates the continuous type steam plating system with e-beam generators and ion generators in the present invention.

FIG. 5 illustrates the continuous type sputter plating system with e-beam generators and ion generators in the present invention.

FIG. 6 is a simulation spectral graph in the present invention.

FIG. 7 is a graph illustrating the relationship between penetration rate and wavelength.

FIG. 8 is a graph illustrating the relationship between penetration rate and wavelength if the sputter system is used.

FIG. 9 is a graph illustrating the relationship between penetration rate and wavelength if a material that can not block the entry of water vapor is used for the third layer of membrane.

FIG. 10 is a graph illustrating the relationship between penetration rate and wavelength if a material that can block the entry of water vapor is used for the third layer of membrane.

### DETAILED DESCRIPTION OF THE PREFERRED EMBODIMENT

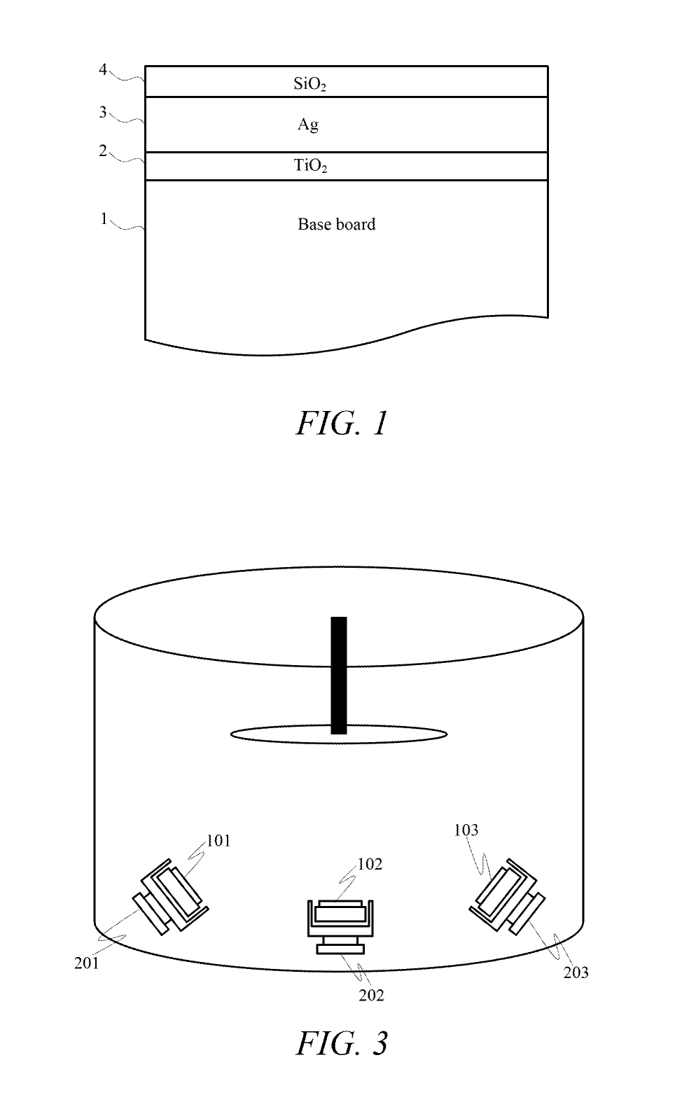

Please see FIG. 1, which schematically illustrates the structure of the TCO coating of the present invention. The TCO coating of the present invention comprises a base board 1, a first layer of membrane 2, a second layer of membrane 3 and a third layer of membrane 4.

The first layer of membrane 2 is plated on the base board 1. The first layer of membrane 2 is made of a material (such as titanium dioxide and other types of oxides) with a work function higher than that of the material (such as metals that have a surface plasma resonance effect under the visible light with a wavelength less than 100 nm, such as gold, silver, copper, aluminum and tellurium) of the second layer of membrane 3 and with a refractive index higher that that of the material of the base board 1 and that of the material (such as silicon oxide and other types of oxides) of the third layer of membrane 4.

The second layer of membrane 3 is plated on the first layer of membrane 2. The work function of the material of the second layer of membrane 3 is smaller than that of the material of the first layer of membrane 2 and that of the material of the third layer of membrane 4. The third layer of membrane 4 is plated on the second layer of membrane 3. In addition, the material (such as gold, silver, copper, aluminum and tellurium) of the second layer of membrane 3 must be a material that has a surface plasma resonance effect under the visible light with a wavelength less than 100 nm. The real number part of the dielectric coefficient of the material is less than zero and the absolute value of the imaginary number part of the dielectric coefficient is less than the absolute value of the real number part of the dielectric coefficient.

The third layer of membrane 4 is plated on the second layer of membrane 3. The material of the third layer of membrane 4 has a work function higher than that of the second layer of membrane 3 and a refractive index smaller than that of the material of the first layer of membrane 2. In addition, the material (such as silicon oxide and other types of oxides) of the third layer of membrane 4 can block the entry of water vapor.

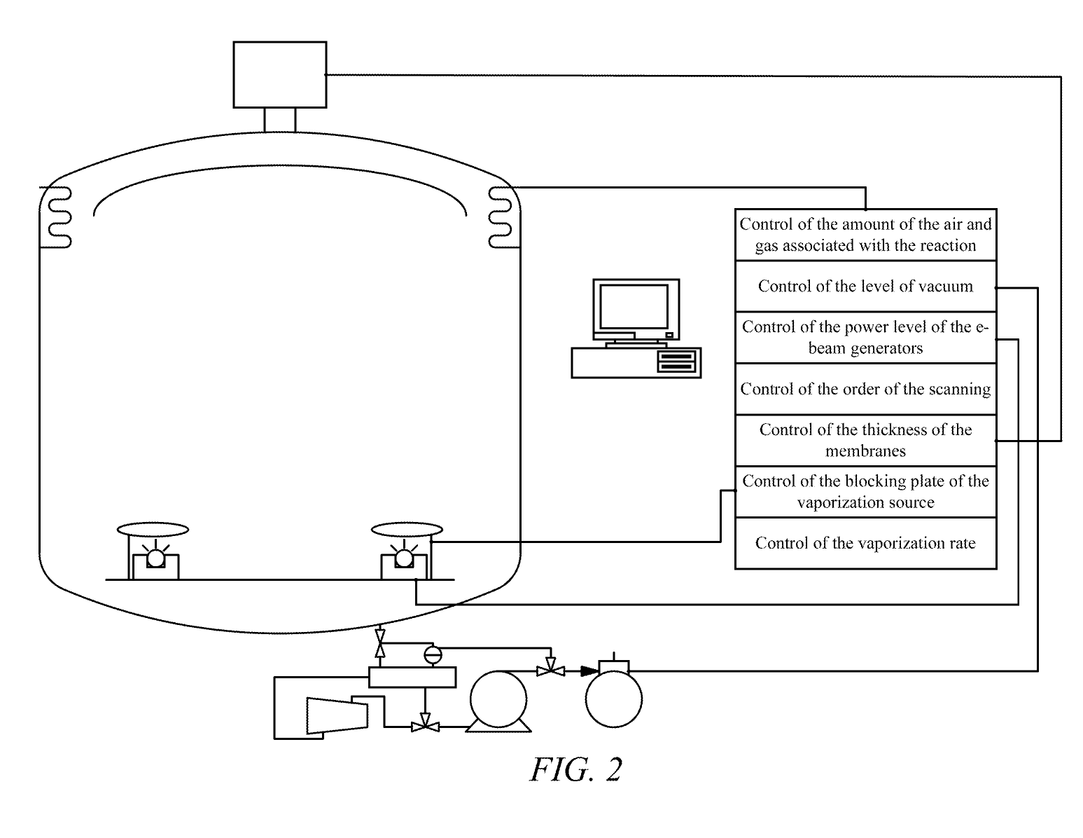

The TCO coating of the present invention may be manufactured by the steam plating system or the sputter system. In the steam plating system, steam plating is carried out under the room temperature and ion generators and e-beam generators are used (as shown in FIG. 2). Therefore, the coating may be a higher density, the steam plating may be carried out under a lower temperature and the thickness of the metallic layer may be modified or adjusted. In addition, by using such steam plating, the TCO coating may have a higher penetration rate (about 85%) and a lower resistivity (about 5.6 ohms/sq). The ion generators are used to modify or adjust the thickness of the metallic membrane and such adjustment is difficult to achieve in the making of a very thin metallic membrane.

In the sputter system, as shown in FIG. 3, the TCO coating is manufactured under the room temperature and in an environment without the presence of oxygen. In addition, DC power is used to carry out the plating of the metallic target material and RF power is used to carry out the plating of the oxide target material. Also, in the present invention, materials with different levels of refractive indices are utilized to enhance the penetration rate of the TCO coating and a material that can block the entry of water vapor is used so that the TCO coating may block the entry of water vapor.

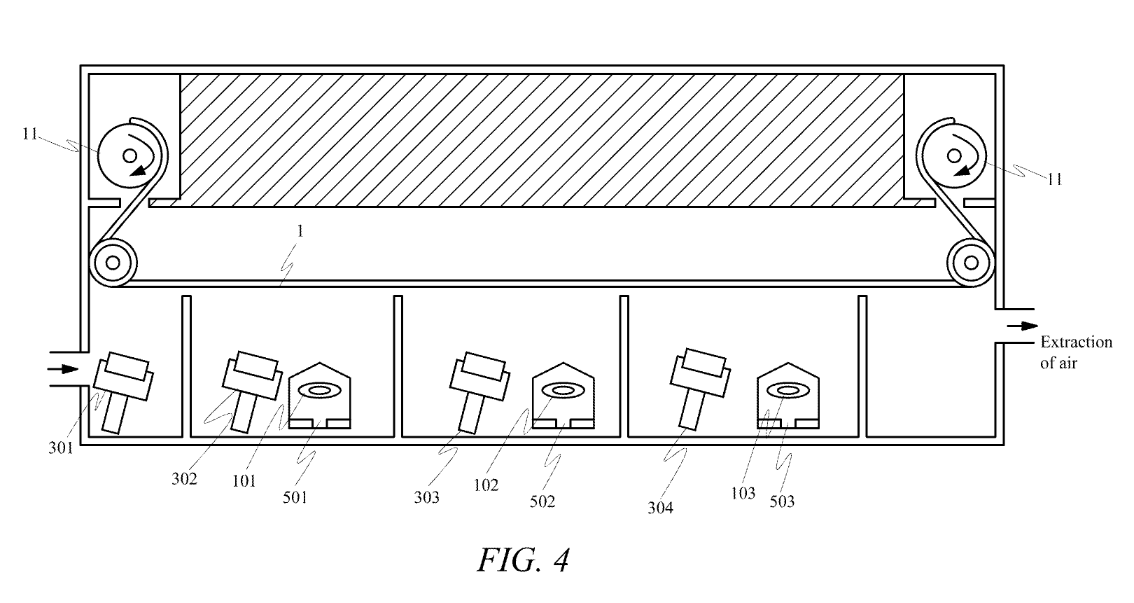

Please see FIG. 4, which illustrates the continuous type steam plating system with e-beam generators and ion generators in the present invention. TCO coatings are made by the e-beam generators and ion generators. Because steam plating is carried out under the room temperature, such steam plating may be carried out continuously. The steam plating system will be elaborated in the following:
1. The flexible base board 1 is taken to the first region by the roller. The ion generator 301 cleans the surfaces of the base board 1.
2. In the second region, an e-beam generator 501 heats up the sputter target material 101. Then the e-beam generator 501 and the ion generator 302 jointly carry out the steam plating of the first layer of membrane 2 on the base board 1. In addition, the sputter target material 101 should have a refractive index higher than that of the base board 1 and that of the third layer of membrane 4.
3. In the third region, an e-beam generator 502 heats up the sputter target material 102. Then the e-beam generator 502 and the ion generator 303 jointly carry out the steam plating of the second layer of membrane 3. In addition, the sputter target material 102 should have a work function lower than that of the sputter target material 101 of the second region and that of the sputter target material 103 of the fourth region.
4. In the fourth region, an e-beam generator 503 heats up the sputter target material 103. Then the e-beam generator 503 and the ion generator 304 jointly carry out the steam plating of the third layer of membrane 4. In addition, the sputter target material 103 should have a work function higher than that of the sputter target material 102 of the third region and a refractive index smaller than that of the sputter target material 101 of the second region and should be a material that can block the entry of water vapor. Then the processed board is moved out by the roller.

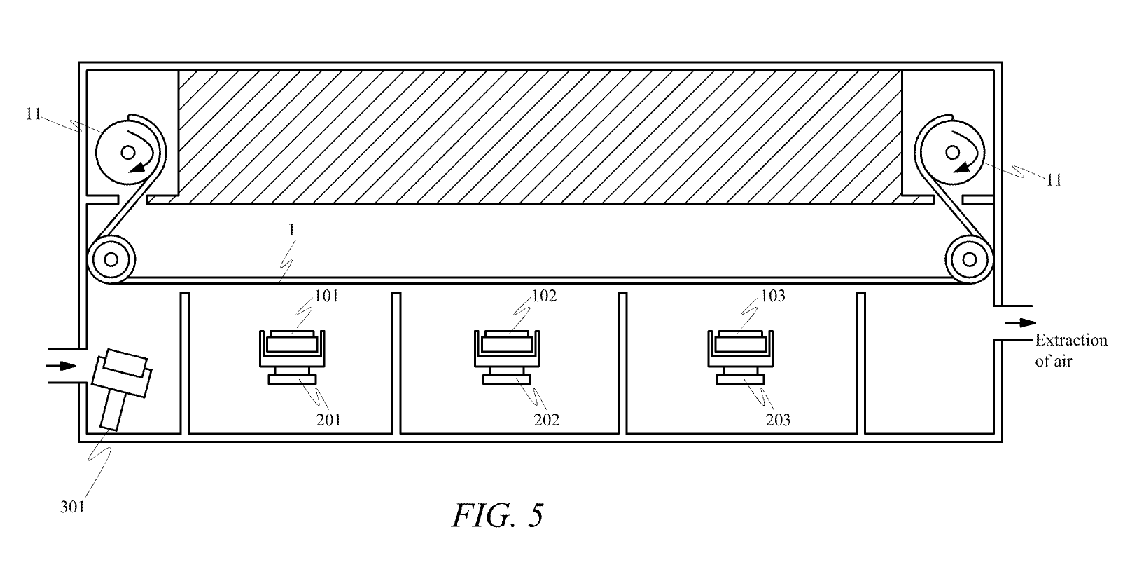

Please see FIG. 5, which illustrates a continuous sputter system of the present invention. Because such sputter plating is carried out under the room temperature, such sputter plating may be carried out continuously. The continuous sputter system includes the following four steps.
1. The flexible base board 1 is taken to the first region by the roller. The ion generator 301 cleans the surfaces of the base board 1.
2. In the second region, a sputter 201 acts on the sputter target material 101 (an oxide) and carries out the plating of the first layer of membrane 2 on the base board 1.
3. In the third region, a sputter 202 acts on the sputter target material 102 (a metal) and carries out the plating of the second layer of membrane 3 on the base board 1.
4. In the fourth region, a sputter 203 acts on the sputter target material 103 (an oxide) and carries out the plating of the third layer of membrane 4 on the base board 1. Then the processed board is moved out by the roller.

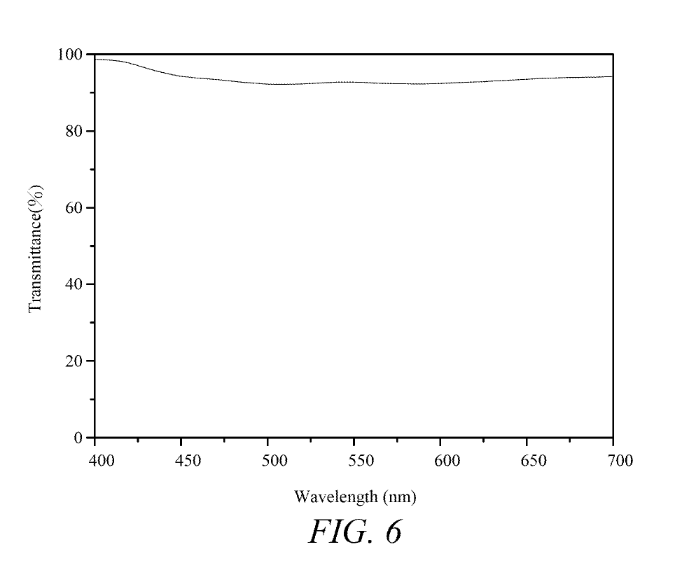

Please see FIG. 6, which is a simulation spectral graph in the present invention. The TCO coating is manufactured according to electromagnetic field simulation software basing on the Maxwell Equations. In FIG. 6, a coating (SiO₂(70 nm)/Ag film(10 nm)/TiO₂(17 nm)) (the first layer of membrane\the second layer of membrane\the third layer of membrane) is used for the simulation of penetration rate. Without taking consideration of the scattering, reflection and absorption of the glass base board and the absorption by the titanium oxide membrane near 387 nm, the average penetration rate of the board in the range of the visible light is 93.7%. In FIG. 6, penetration rate has a higher numerical value at several wavelengths and this is due to the surface plasma resonance effect on the silver membrane.

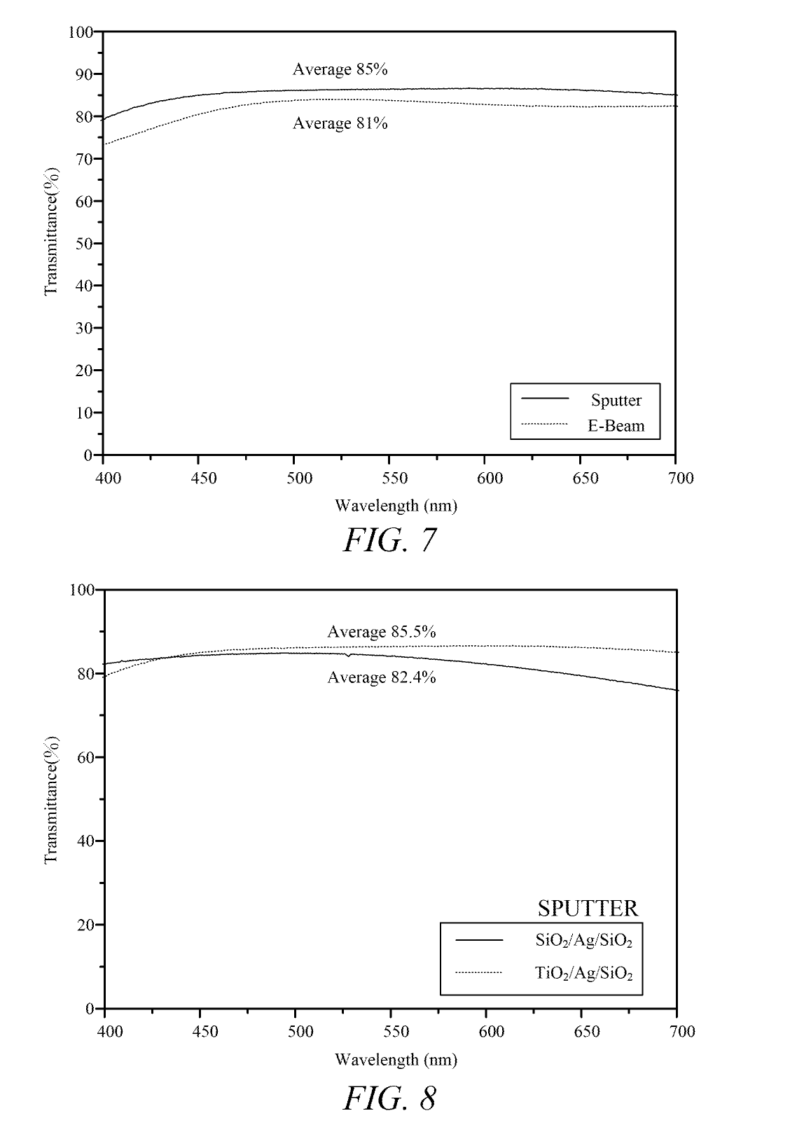

Please see FIG. 7, which is a graph illustrating the relationship between penetration rate and wavelength. If the sputter system is used, the average penetration rate of the visible light is about 85%. If the e-beam generator (assisted by the ion generators) is used, the average penetration rate of the visible light is about 81%.

Please see FIG. 8, which is a graph illustrating the relationship between penetration rate and wavelength if the sputter system is used. A first type of coating is SiO₂\Ag\SiO₂ (the first layer of membrane\the second layer of membrane\the third layer of membrane). A second type of coating is TiO₂\Ag\SiO₂ (the first layer of membrane\the second layer of membrane\the third layer of membrane). The material (titanium oxide) of the first layer of membrane 2 has a refractive index higher than that of the material (silicon oxide) of the third layer of membrane 4. The average visible light penetration rate of the second type of coating is 85.5%. Regarding the first type of coating, the material (silicon oxide) of the first layer of membrane 2 has a refractive index equal to that of the material (silicon oxide) of the third layer of membrane 4. The average visible light penetration rate of the first type of coating is 82.4%.

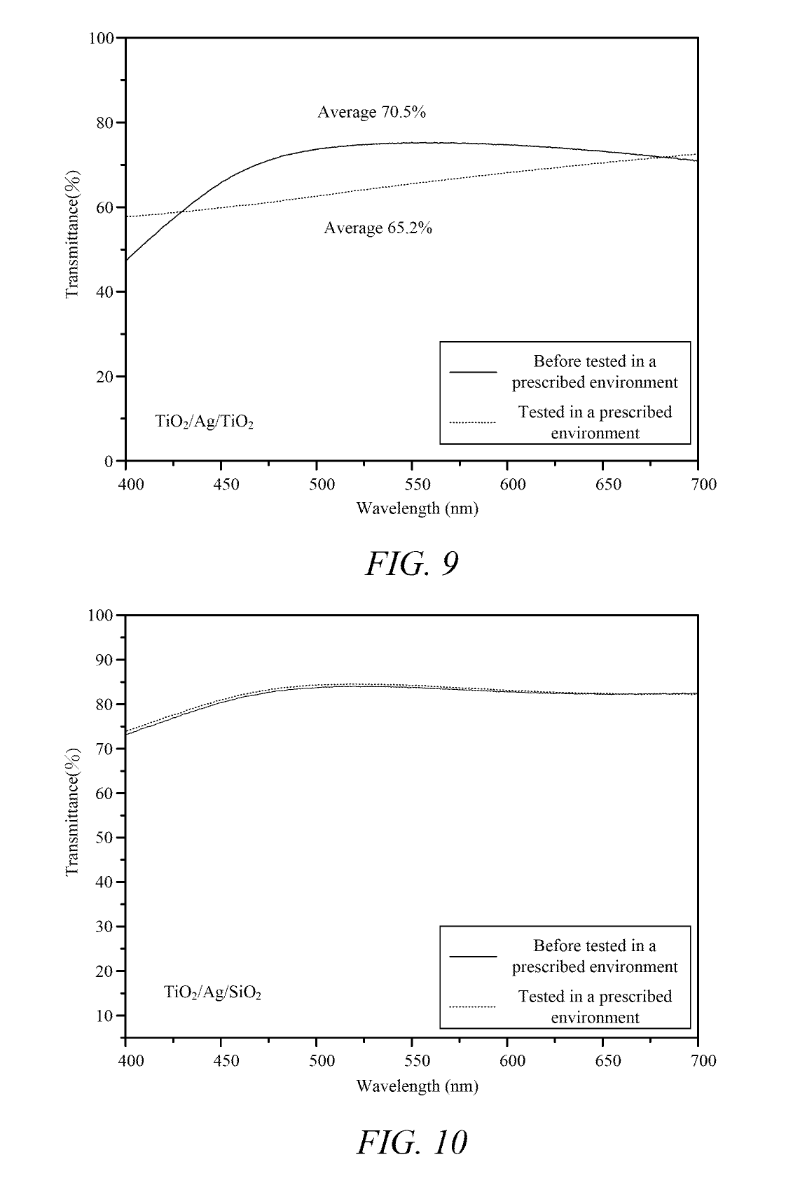

Please see FIG. 9, which is a graph illustrating the relationship between penetration rate and wavelength if a material that can not block the entry of water vapor is used for the third layer of membrane 4. The coating of TiO₂\Ag\TiO₂ (the third layer of member being TiO₂) is tested in an environment meeting the prescriptions of the ISO 9211. The average visible light transmittance drops to 65.2% from 75.5%.

Please see FIG. 10, which is a graph illustrating the relationship between penetration rate and wavelength if a material that can block the entry of water vapor is used for the third layer of membrane. The coating of TiO₂\Ag\SiO₂ (the third layer of member being SiO₂) is tested in an environment meeting the prescriptions of the ISO 9211. The average visible light transmittance is 81.5% (not showing any drop).

In comparison to the prior art, the present invention has the following advantages:
1. Because the manufacturing method of the present invention may be carried out under the room temperature, base boards that are made of polymer and materials that can not withstand high temperatures may be used for the base board.
2. Because steam plating and sputter plating are used, less time is needed in the production, production cost is lowered and mass-production may be achieved.
3. Ion generators are used to modify or adjust the thickness of the metallic membranes and such adjustment is difficult to achieve in the making of very thin metallic membrane.
4. The TCO coating in the present invention comprises materials having higher and lower refractive indices. Also, material that can block the entry of water vapor is used to enable the coating to withstand vapor.

Although a preferred embodiment of the present invention has been described in detail hereinabove, it should be understood that the preferred embodiment is to be regarded in an illustrative manner rather than a restrictive manner, and all variations and modifications of the basic inventive concepts herein taught still fall within the scope of the present invention.

LIST OF REFERENCE NUMERALS

| | | | |
|---|---|---|---|
| 1 | Base board | 2 | First layer of membrane |
| 3 | Second layer of membrane | 4 | Third layer of membrane |
| 101 | Sputter target material | 11 | roller |
| | comprising an oxide | | |
| 103 | Sputter target material | 102 | Sputter target material |
| | comprising an oxide | | comprising a metal |
| 202 | Sputter | 201 | Sputter |
| 301 | Ion generator | 203 | Sputter |
| 303 | Ion generator | 302 | Ion generator |
| 501 | E-beam generator | 304 | Ion generator |
| 503 | E-beam generator | 502 | E-beam generator |

What is claimed is:

1. A TCO (transparent conducting oxide) coating, comprising:
a base board;
a first layer of membrane, plated on the base board;
a second layer of membrane, plated on the first layer of membrane; and
a third layer of membrane, plated on the second layer of membrane
wherein the material of the first layer of membrane has a work function higher than that of the material of the second layer of membrane and a refractive index larger that that of the material of the base board and that of the material of the third layer of membrane;
the material of the second layer of membrane has a work function smaller than that of the material of the first layer of membrane and that of the material of the third layer of membrane; and
the material of the third layer of membrane has a work function higher than that of the second layer of membrane and a refractive index smaller than that of the material of the first layer of membrane.

2. The TCO coating as in claim 1, wherein the material of the first layer of membrane is an oxide.

3. The TCO coating as in claim 2, wherein the material of the first layer of membrane is titanium dioxide or silicon dioxide.

4. The TCO coating as in claim 1, wherein the material of the second layer of membrane is a metal with a surface plasma resonance effect in the range of visible light, and wherein the real number part of the dielectric coefficient of the material is less than zero and the absolute value of the imaginary number part of the dielectric coefficient is less than the absolute value of the real number part of the dielectric coefficient.

5. The TCO coating as in claim 4, wherein the material of the second layer of membrane is gold, silver, copper, aluminum, or tellurium.

6. The TCO coating as in claim 1, wherein the material of the third layer of membrane is an oxide capable of blocking entry of water vapor.

7. The TCO coating as in claim 6, wherein the material of the third layer of membrane is silicon oxide.

8. A continuous manufacturing method of a TCO coating, the method comprising the following steps:
(1) taking a flexible base board to a first region by a roller and cleaning the flexible base board with an ion generator;
(2) in a second region, heating up a sputter target material with an e-beam generator and carrying out steam plating of a first layer of membrane on the base board using the e-beam generator and an ion generator jointly;
(3) in a third region, heating up a sputter target material with an e-beam generator and carrying out steam plating of a second layer of membrane using the e-beam generator and an ion generator jointly;
(4) in a fourth region, heating up a sputter target material with an e-beam generator and carrying out steam plating of a third layer of membrane using the e-beam generator and an ion generator jointly; and
(5) moving the processed board out by the roller.

9. The manufacturing method as in claim 8, wherein, in the second region, the sputter target material is an oxide with a refractive index higher than that of the base board and that of the third layer of membrane.

10. The manufacturing method as in claim 8, wherein, in the third region, the sputter target material is a metal with a work function smaller than that of the sputter target material of the second region and that of the sputter target material of the fourth region.

11. The manufacturing method as in claim 8, wherein, in the fourth region, the sputter target material is an oxide that is capable of blocking entry of water vapor and that has a work function higher than that of the sputter target material of the third region and a refractive index smaller than that of the sputter target material of the second layer of membrane.

12. A continuous manufacturing method of a TCO coating by using a sputter system, the method comprising the following steps:
(1) taking a flexible base board to a first region by a roller and cleaning the base board with an ion generator;
(2) in a second region, applying a sputter on a sputter target material and carrying out steam plating of a first layer of membrane on the base board;
(3) in a third region, applying a sputter on a sputter target material and carrying out steam plating of a second layer of membrane on the base board;
(4) in a fourth region, applying a sputter on a sputter target material and carrying out steam plating of a third layer of membrane on the base board; and
(5) moving the processed board out by the roller.

13. The manufacturing method as in claim 12, wherein, in the second region, the sputter target material is an oxide with a refractive index higher than that of the base board and that of the third layer of membrane.

14. The manufacturing method as in claim 12, wherein, in the third region, the sputter target material is a metal with a work function smaller than that of the sputter target material of the second region and that of the sputter target material of the fourth region.

15. The manufacturing method as in claim 12, wherein, in the fourth region, the sputter target material is an oxide that is capable of blocking entry of water vapor and that has a work function higher than that of the sputter target material of the third region and a refractive index smaller than that of the sputter target material of the second layer of membrane.
